(19) United States
(12) Patent Application Publication
(10) Pub. No.: US 2007/0108635 A1
(43) Pub. Date: May 17, 2007

(54) INTEGRATED CIRCUIT PACKAGE SYSTEM

(75) Inventor: Han Shin Youn, Icheon-si (KR)

Correspondence Address: ISHIMARU & ZAHRT LLP, 333 W. EL CAMINO REAL, SUITE 330, SUNNYVALE, CA, 94087, US

(73) Assignee: STATS CHIPPAC LTD., Singapore (SG)

(21) Appl. No.: 11/276,947

(22) Filed: Mar. 17, 2006

Related U.S. Application Data
(60) Provisional application No. 60/594,680, filed on Apr. 28, 2005.

(51) Int. Cl. H01L 23/28

(52) U.S. Cl. 257/787

(57) ABSTRACT

An integrated circuit package system is provided forming an integrated circuit die having a non-active side and an active side, elevating a die paddle above an external interconnect, attaching the active side on a bottom side of the die paddle, and partially encapsulating the integrated circuit die, the die paddle, and the external interconnect with a top side of the die paddle and the non-active side exposed.

### CROSS-REFERENCE TO RELATED APPLICATION

This application claims the benefit of U.S. Provisional Patent Application Ser. No. 60/594,680 filed Apr. 28, 2005, and the subject matter thereof is hereby incorporated herein by reference thereto.

### TECHNICAL FIELD

The present invention relates generally to integrated circuit packages and more particularly to integrated circuit packages with a heat sink.

### BACKGROUND ART

Every new generation of integrated circuits with increased operating frequency, performance and the higher level of large scale integration have underscored the need for back-end semiconductor manufacturing to increase the heat management capability within an encapsulated package. It is well acknowledged that when a semiconductor device becomes denser in term of electrical power consumption per unit volume, heat generated is also increases correspondingly. More and more packages are now designed with an external heat sink or heat slug to enhance the ability of heat being dissipated to the package ambient environment. As the state of the art progresses, the ability to adequately dissipate heat is often a constraint on the rising complexity of package architecture design, smaller footprint, higher device operating speed and power consumption.

Modem consumer electronics, such as smart phones, personal digital assistants, and location based services devices, are packing more integrated circuits into an ever shrinking physical space with expectations for decreasing cost. Contemporary consumer electronics expose integrated circuits and packages to more demanding and sometimes new environmental conditions, such as cold, heat, and humidity requiring integrated circuit packages to provide robust thermal management structures. As more functions are packed into the integrated circuits and more integrated circuits into the package, more heat is generated degrading the performance, the reliability and the life time of the integrated circuits. Numerous technologies have been developed to meet these requirements. Some of the research and development strategies focus on new package technologies while others focus on improving the existing and mature package technologies. Research and development in the existing package technologies may take a myriad of different directions.

One proven way to reduce cost is to use mature package technologies with existing manufacturing methods and equipments. Paradoxically, the reuse of existing manufacturing processes does not typically result in the reduction of package dimensions. Existing packaging technologies struggle to cost effectively meet the ever demanding thermal requirements of today's integrated circuits and packages. Most integrated circuit devices use molded plastic epoxy as an epoxy molding compound (EMC) for protecting package. But the poor heat dissipation property of EMC sometimes leads to device malfunctions. Current package profiles have not been reduced below 0.8 mm.

Thus, a need still remains for an integrated circuit package system providing low cost manufacturing, improved reliability, increased thermal performance, and reduced integrated circuit package dimensions below 0.8 mm. In view of the ever-increasing need to save costs and improve efficiencies, it is more and more critical that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides an integrated circuit package system including forming an integrated circuit die having a non-active side and an active side, elevating a die paddle above an external interconnect, attaching the active side on a bottom side of the die paddle, and partially encapsulating the integrated circuit die, the die paddle, and the external interconnect with a top side of the die paddle and the non-active side exposed.

Certain embodiments of the invention have other aspects in addition to or in place of those mentioned or obvious from the above. The aspects will become apparent to those skilled in the art from a reading of the following detailed description when taken with reference to the accompanying drawings.

### BRIEF DESCRIPTION OF THE DRAWINGS

FIG. 1 is a cross-sectional view of an integrated circuit package system in an embodiment of the present invention;

FIG. 2 is a top view of a lead frame in an embodiment of the present invention;

FIG. 3 is a cross-sectional view of the lead frame along the segment line 3-3′ of FIG. 2;

FIG. 4 is a top view of a tie bar configuration in an alternative embodiment of the present invention;

FIG. 5 is a cross-sectional view of the tie bar configuration along the segment line 5-5′ of FIG. 4; and

FIG. 6 is a flow chart of an integrated circuit package system for manufacture of the integrated circuit package system in an embodiment of the present invention.

### BEST MODE FOR CARRYING OUT THE INVENTION

In the following description, numerous specific details are given to provide a thorough understanding of the invention. However, it will be apparent that the invention may be practiced without these specific details. In order to avoid obscuring the present invention, some well-known system configurations, and process steps are not disclosed in detail. Likewise, the drawings showing embodiments of the apparatus are semi-diagrammatic and not to scale and, particularly, some of the dimensions are for the clarity of presentation and are shown greatly exaggerated in the figures. In addition, where multiple embodiments are disclosed and described having some features in common, for clarity and ease of illustration, description, and comprehension thereof, similar and like features one to another will ordinarily be described with like reference numerals.

The term “horizontal” as used herein is defined as a plane parallel to the conventional integrated circuit surface, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “upper”, “over”, and “under”, are defined with respect to the horizontal plane.

The term “processing” as used herein includes deposition of material, patterning, exposure, development, etching, cleaning, molding, and/or removal of the material or as required in forming a described structure.

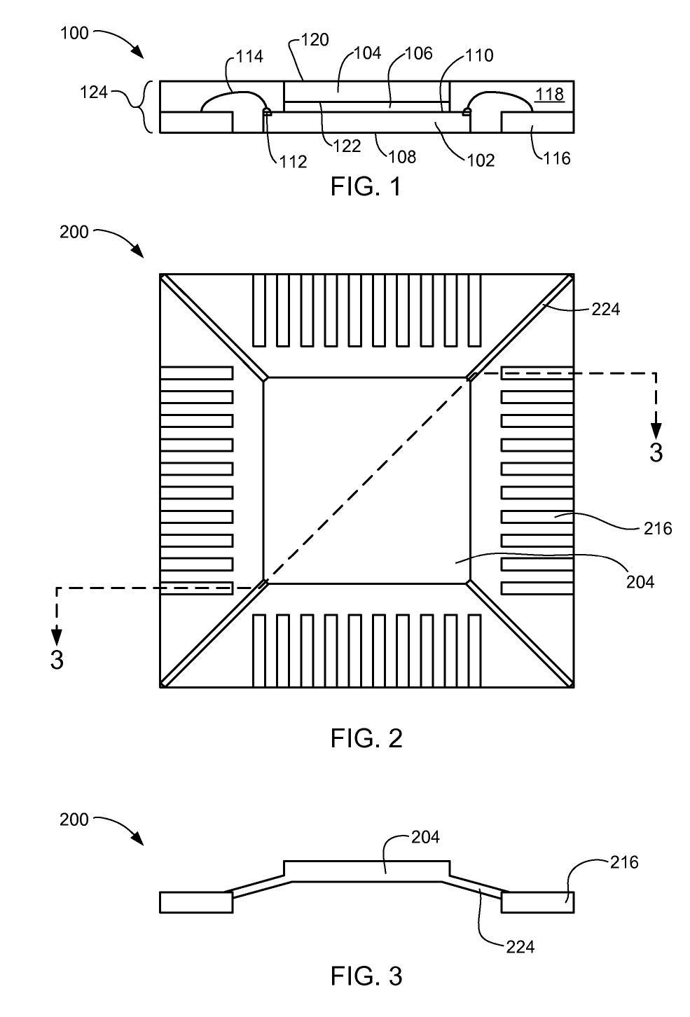

Referring now to FIG. 1, therein is shown a cross-sectional view of an integrated circuit package system 100 in an embodiment of the present invention. The integrated circuit package system 100, such as a terminal lead frame chip-scale package (TLFCSP), includes an integrated circuit die 102 attached on a die paddle 104 with an adhesive 106, such as a die-attach adhesive or a thermally conductive adhesive. The integrated circuit die 102 has a non-active side 108 and an active side 110 with circuitry and bond pads 112 fabricated thereon. Internal interconnects 114, such as bond wires, ribbon bond wires, or planar interconnects, connect between the bond pads 112 of the integrated circuit die 102 and tops of external interconnects 116, such as terminal leads.

An encapsulation 118, such as an epoxy molding compound (EMC), covers the internal interconnects 114 while partially covering the integrated circuit die 102, the die paddle 104, and the external interconnects 116. A top side 120 of the die paddle 104, the non-active side 108 of the integrated circuit die 102, and bottoms as well as sides of the external interconnects 116 are exposed to the outside of the integrated circuit package system 100. The integrated circuit die 102 and the external interconnects 116 may undergo a planarization process to have the integrated circuit die 102 and the bottoms of the external interconnects 116 in substantially in the same horizontal plane. Planarization process, such as chemical mechanical planarization, may also be applied to expose the die paddle 104. A film assisted molding may also be used to expose the required surfaces. The external interconnects 116 connect to the next system level (not shown), such as a printed circuit board, another integrated circuit package, or a combination thereof.

For illustrative purpose, the external interconnects 116 are shown as rectangular, although it is understood that the external interconnects 116 may not be rectangular, such as having inner portions of the external interconnects 116 half etched providing registration in the encapsulation 118. Also for illustrative purpose, the external interconnects 116 are shown in a single row, although it is understood that the configuration of the external interconnects 116 may be more than one row.

Heat is generated from the circuitry on the active side 110 of the integrated circuit die 102. The die paddle 104 may also serve as a heat sink providing a thermal path from the integrated circuit die 102 through the adhesive 106 and the die paddle 104 to ambient. The heat from the integrated circuit die 102 may also flow to ambient through the non-active side 108. The encapsulation 118 as well as the external interconnects 116 may provide additional thermal dissipation paths but most of the thermal dissipation will be through the die paddle 104 and the non-active side 108. Thermal management will improve the reliability and life time of the integrated circuit die 102.

The die paddle 104 is elevated or upset above the horizontal plane of the external interconnects 116 such that the active side 110 of the integrated circuit die 102 attaches to a bottom side 122 of the die paddle 104 with the non-active side 108 substantially in the same horizontal plane as the bottoms of the external interconnects 116. The die paddle 104 does not impede the connections of the internal interconnects 114 to the bond pads 112 of the integrated circuit die 102. The active side 110 and the tops of the external interconnects 116 are at similar height providing a shorter distance for the internal interconnects 114. The top side 120 of the die paddle 104 is above the height of the internal interconnects 114.

This minimal distance between the bond pads 112 and the external interconnects 116 significantly reduces the risk of adverse crossings of the internal interconnects 114 and improves signal transmission. This along with the thermal dissipation paths through the die paddle 104 and the non-active side 108 of the integrated circuit die 102 improves manufacturing yields and lowers overall packaging cost.

The dual function of the die paddle 104 serving as both as a mounting surface and a heat sink for the integrated circuit die 102 along with the low height of the internal interconnects allows the integrated circuit package system 100 to have a low package height 124, such as less than 0.8 mm or approximately 0.5 mm.

Referring now to FIG. 2, therein is shown a top view of a lead frame 200 in an embodiment of the present invention. The lead frame 200 is half etched exposing external interconnects 216, such as terminal leads, for further connections. The lead frame 200 also has tie bars 224 attached to a die paddle 204. The die paddle 204 are shown within the boundary outlined by the external interconnects 216. The lead frame 200 may be processed and singulated to be part of the integrated circuit package system 100 of FIG. 1.

The lead frame 200 may be made from a number of conductive materials, such as copper (Cu), other metals, or metal alloys. The lead frame 200 may also be plated with gold (Ag), a nickel (Ni) palladium (Pd) alloy, silver (Au), or copper oxide. The lead frame 200 may be partially or completely plated. Furthermore, an insulator or pre-plated epoxy, such as liquid type, B-stage, or film type epoxy, may be applied on the lead frame 200. The type of plating may depend upon the need for the die paddle 204 to serve as a heat sink or not as well as the type of materials of the internal interconnects 114 of FIG. 1 to bond to the external interconnects 216.

For illustrative purpose, the external interconnects 216 are shown in a single row, although it is understood that the configuration of the external interconnects 216 may be more than one row. Also for illustrative purpose, the external interconnects 216 are shown as substantially the same dimensions, although it is understood that the external interconnects 216 may not be the same dimensions, such as in a staggered configuration. Further for illustrative purpose, the die paddle 204 is shown as a single element, although it is understood that the die paddle 204 may be composed of different elements or sections, such as a window for optical transmission or sensing.

Referring now to FIG. 3, therein is shown a cross-sectional view of the lead frame 200 along the segment line 3-3′ of FIG. 2. The cross-sectional view depicts the die paddle 204 attached to the tie bars 224 and elevated above the external interconnects 216. The height of the die paddle 204 accommodates the integrated circuit die 102 of FIG. 1 while substantially at the same horizontal plane as the bottoms of the external interconnects 216. For illustrative purpose, the external interconnects 216 are shown as rectangular, although it is understood that the external interconnects 216 may not be rectangular, such as having inner portions of the external interconnects 216 half etched providing registration in the encapsulation 118 of FIG. 1.

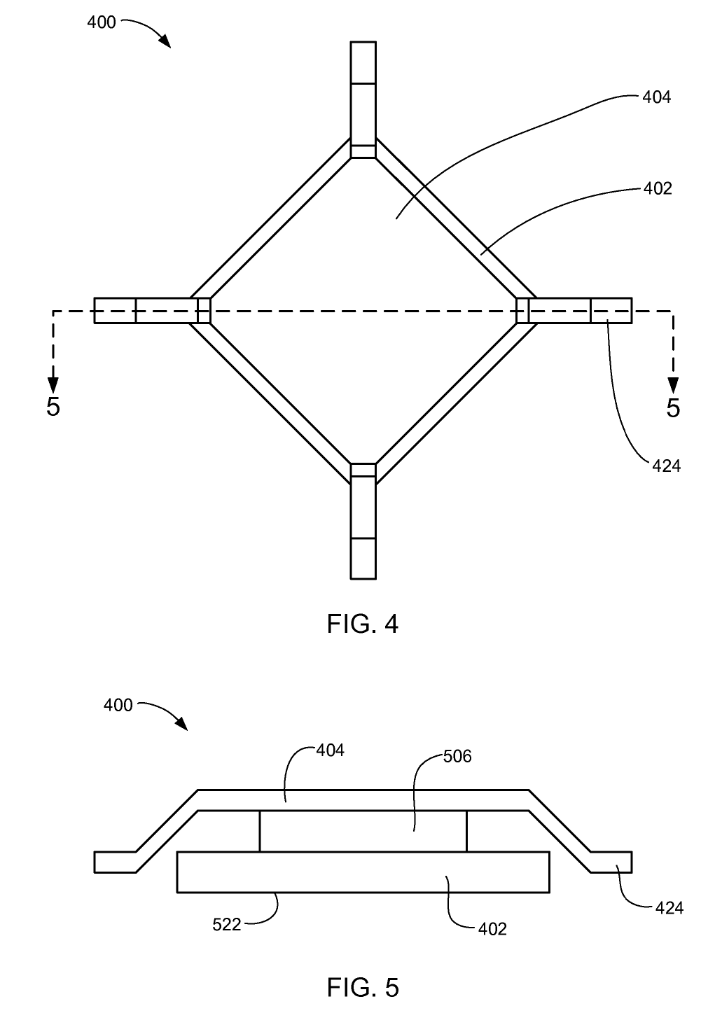

Referring now to FIG. 4, therein is shown a top view of a tie bar configuration 400 in an embodiment of the present invention. The top view depicts a die paddle 404 attached to tie bars 424 and an integrated circuit die 402 attached to the die paddle 404. The integrated circuit die 402 is larger than the die paddle 404 providing sufficient room for electrical connections to the integrated circuit die 402. The die paddle 404 may provide slits or channels (not shown) such that the integrated circuit die 402 may be smaller than the die paddle 404 and the electrical connections may be made through the channels. Even for the integrated circuit die 402 larger than the die paddle 404, the channels may also be used to provide multiple rows of electrical connections to the integrated circuit die 402.

Referring now to FIG. 5, therein is shown a cross-sectional view of the tie bar configuration 400 along the segment line 5-5′ of FIG. 4. The cross-sectional view depicts the tie bars 424 attached to and supporting the die paddle 404. The integrated circuit die 402 attaches to a bottom side 522 of the die paddle 404 with an adhesive 506, such as a die-attach adhesive or a thermally conductive adhesive. The die paddle 404, the adhesive 506, and the tie bars 424 do not impeded electrical connections to the integrated circuit die 402. The die paddle 404 may be elevated or upset by a number of processes, such as a stamp process or half etch process.

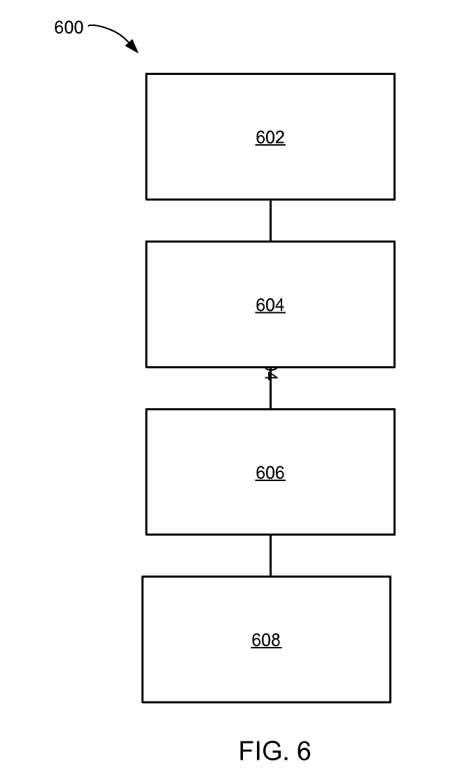

Referring now to FIG. 6, therein is shown a flow chart of an integrated circuit package system 600 for manufacture of the integrated circuit package system 100 in an embodiment of the present invention. The system 600 includes forming an integrated circuit die having a non-active side and an active side in a block 602; elevating a die paddle above an external interconnect in a block 604; attaching the active side on a bottom side of the die paddle in a block 606; and partially encapsulating the integrated circuit die, the die paddle, and the external interconnect with a top side of the die paddle and the non-active side exposed in a block 608.

It has been discovered that the present invention thus has numerous aspects.

It has been discovered that the present invention provides a package height lower than 0.8 mm with improved electrical performance, improved thermal performance, increased reliability, and reduced manufacturing cost. These benefits are attained from the dual function of the die paddle serving as both as a mounting surface and a heat sink for the integrated circuit die along with the reduced distance of the internal interconnects between the integrated circuit die and the external interconnects (terminal leads).

An aspect is that the present invention is that the upset or elevated die paddle accommodates the active side of the integrated circuit die to attach to the underside of the die paddle. The dual function of the die paddle simultaneously lowers the package profile as well as reduces the interconnect distance between the integrated circuit die and the terminal leads.

Another aspect of the present invention is that the dual sided thermal paths from the active side of the integrated circuit die through the die paddle and through the non-active side of the integrated circuit die provides a low cost thermal dissipation system. This dual thermal management structure in this package will improve the reliability and life time of the integrated circuit die.

Yet another aspect of the present invention is that the lead frame used to form the die paddle and the terminal leads may be plated with a number of materials, such as insulators, metals, or alloys, depending on the need of the package.

Thus, it has been discovered that the integrated circuit package system method of the present invention furnishes important and heretofore unknown and unavailable solutions, capabilities, and functional aspects for reducing package height and improving performance in systems. The resulting processes and configurations are straightforward, cost-effective, uncomplicated, highly versatile and effective, can be implemented by adapting known technologies, and are thus readily suited for efficiently and economically manufacturing integrated circuit package devices.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. An integrated circuit package system comprising:
forming an integrated circuit die having a non-active side and an active side;
elevating a die paddle above an external interconnect;
attaching the active side on a bottom side of the die paddle; and
partially encapsulating the integrated circuit die, the die paddle, and the external
interconnect with a top side of the die paddle and the non-active side exposed.

2. The system as claimed in claim 1 further comprising forming a low package height below 0.8 mm.

3. The system as claimed in claim 1 further comprising:
forming a first thermal dissipation path from the active side through the die paddle to ambient; and
forming a second thermal dissipation path from the active side through the non-active side to ambient.

4. The system as claimed in claim 1 wherein attaching the active side on the bottom side of the die paddle includes applying an adhesive between the integrated circuit die and the die paddle.

5. The system as claimed in claim 1 further comprising electrically connecting the active side and the external interconnect.

6. An integrated circuit package system comprising:
forming an integrated circuit die having a non-active side and an active side having circuitry provided thereon;
elevating a die paddle above an external interconnect with a tie bar attached to the die paddle;
attaching the active side on a bottom side of the die paddle with an adhesive; and
partially encapsulating the integrated circuit die, the die paddle, and the external interconnect with a top side of the die paddle, the non-active side, and a portion of the external interconnect exposed.

7. The system as claimed in claim 6 further comprising forming the die paddle and the external interconnects from a lead frame comprised of metals or alloys.

8. The system as claimed in claim 6 further comprising forming the die paddle and the external interconnects from a lead frame plated with a material comprised of gold, silver, copper oxide, or nickel palladium alloy.

9. The system as claimed in claim 6 further comprising forming the die paddle and the external interconnects from a lead frame pre-plated with a material comprised of an insulator, an epoxy, a liquid type epoxy, a B-stage epoxy, or a film type epoxy.

10. The system as claimed in claim 6 wherein attaching the active side on the bottom side of the die paddle has the integrated circuit die larger than the die paddle.

11. An integrated circuit package system comprising:
an integrated circuit die having a non-active side and an active side;
a die paddle above an external interconnect;
the active side on a bottom side of the die paddle; and
a first encapsulation to partially cover the integrated circuit die, the die paddle, and
the external interconnect with a top side of the die paddle and the non-active side exposed.

12. The system as claimed in claim 11 further comprising a low package height below 0.8 mm.

13. The system as claimed in claim 11 further comprising:
a first thermal dissipation path from the active side through the die paddle to ambient; and
a second thermal dissipation path from the active side through the non-active side to ambient.

14. The system as claimed in claim 11 wherein the active side on the bottom side of the die paddle includes an adhesive between the integrated circuit die and the die paddle.

15. The system as claimed in claim 11 further comprising an internal interconnect between the active side and the external interconnect.

16. The system as claimed in claim 11 wherein:
the integrated circuit die having the non-active side and the active side has circuitry provided on the active side;
the die paddle above the external interconnect is attached to a tie bar;
the active side on the bottom side of the die paddle has an adhesive between the active side and the bottom side; and
the first encapsulation to partially cover the integrated circuit die, the die paddle, and
the external interconnect with the top side of the die paddle and the non-active side exposed also exposes a portion of the external interconnect.

17. The system as claimed in claim 16 further comprising the die paddle and the external interconnects comprised of metals or alloys.

18. The system as claimed in claim 16 further comprising the die paddle and the external interconnects plated with a material comprised of gold, silver, copper oxide, or nickel palladium alloy.

19. The system as claimed in claim 16 further comprising the die paddle and the external interconnects pre-plated with a material comprised of an insulator, an epoxy, a liquid type epoxy, a B-stage epoxy, or a film type epoxy.

20. The system as claimed in claim 16 wherein the active side on the bottom side of the die paddle has the integrated circuit die larger than the die paddle.
